(19) United States
(12) Patent Application Publication
(10) Pub. No.: US 2021/0362372 A1
(43) Pub. Date: Nov. 25, 2021

(54) METHOD FOR MANUFACTURING CERAMIC SUBSTRATE AND CERAMIC SUBSTRATE

(71) Applicant: Murata Manufacturing Co., Ltd., Nagaokakyo-shi (JP)

(72) Inventor: Koki Sai, Nagaokakyo-shi (JP)

(21) Appl. No.: 17/391,810

(22) Filed: Aug. 2, 2021

Related U.S. Application Data
(63) Continuation of application No. PCT/JP2020/008257, filed on Feb. 28, 2020.

(30) Foreign Application Priority Data
Mar. 29, 2019 (JP) 2019-068268

(51) Int. Cl. B28B 11/24; H05K 1/03; B32B 9/00; B32B 3/26; B32B 37/06

(52) U.S. Cl. CPC B28B 11/243; H05K 1/0306; B32B 37/06; B32B 3/263; B32B 9/005

(57) ABSTRACT

A method for manufacturing a ceramic substrate that includes preparing a plurality of ceramic green sheets, at least one of the plurality of ceramic green sheets having a disappearance material that disappears by firing in a recessed portion formation planned region of the at least one of the plurality of ceramic green sheets; forming a mother multilayer body by laminating the plurality of ceramic green sheets such that the at least the one ceramic green sheet having the disappearance material is positioned on an uppermost layer of the mother multilayer body; and forming a recessed portion in the mother multilayer body before firing by pressing the recessed portion formation planned region of the mother multilayer body.

### CROSS REFERENCE TO RELATED APPLICATIONS

The present application is a continuation of International application No. PCT/JP2020/008257, filed Feb. 28, 2020, which claims priority to Japanese Patent Application No. 2019-068268, filed Mar. 29, 2019, the entire contents of each of which are incorporated herein by reference.

### FIELD OF THE INVENTION

The present invention relates to a method for manufacturing a ceramic substrate and a ceramic substrate.

### BACKGROUND OF THE INVENTION

A ceramic substrate is used as a mounting substrate on which an electronic component is mounted, or a package that houses an electronic component. As for the ceramic substrate (electronic component housing package) described in Patent Document 1, an upper surface of a ceramic green sheet is pressed to create a recessed portion such that the recessed portion is formed on the ceramic substrate after firing.
Patent Document 1: Japanese Unexamined Patent Application Publication No. 2015-170756

### SUMMARY OF THE INVENTION

In Patent Document 1, in the press process, pressure applied to the ceramic green sheet differs between a region in which the recessed portion of the ceramic green sheet is formed and a region in which the recessed portion is not formed. Accordingly, in the ceramic green sheet where the recessed portion is processed, there is a density distribution along the plane between the region having the recessed portion and the region not having the recessed portion. For this reason, warpage may occur in the ceramic substrate after firing.

An object of the present invention is to provide a method for manufacturing a ceramic substrate capable of suitably suppressing warpage and a ceramic substrate.

A method for manufacturing a ceramic substrate according to an aspect of the present invention includes preparing a plurality of ceramic green sheets, at least one of the plurality of ceramic green sheets having a disappearance material that disappears by firing in a recessed portion formation planned region of the at least one of the plurality of ceramic green sheets; forming a mother multilayer body by laminating the plurality of ceramic green sheets such that the at least the one ceramic green sheet having the disappearance material is positioned on an uppermost layer of the mother multilayer body; and forming a recessed portion in the mother multilayer body before firing by pressing the recessed portion formation planned region of the mother multilayer body.

A method for manufacturing a ceramic substrate according to another aspect of the present invention includes preparing a plurality of ceramic green sheets, at least one of the plurality of ceramic green sheets having a high shrinkage rate material having a higher shrinkage rate in firing than a shrinkage rate in firing of the plurality of ceramic green sheets in a recessed portion formation planned region of the at least one of the plurality of ceramic green sheets; forming a mother multilayer body by laminating the plurality of the ceramic green sheets such that the at least the one ceramic green sheet having the high shrinkage rate material is positioned on an uppermost layer of the mother multilayer body; and forming a recessed portion in the mother multilayer body before firing by pressing the recessed portion formation planned region of the mother multilayer body.

A ceramic substrate according to an aspect of the present invention includes a substrate comprising a plurality of laminated ceramic layers, the substrate having a bottom portion with a mounting surface; a wall portion on the bottom portion of the substrate and surrounding the mounting surface; and a high shrinkage rate material having a higher shrinkage rate in firing than a shrinkage rate in firing of the plurality of ceramic layers laminated on the plurality of ceramic layers in a region overlapping with the mounting surface, wherein an orientation of a grain boundary indicating an interlayer between the plurality of ceramic layers is curved along the mounting surface and an inner wall of the wall portion.

According to the present invention, it is possible to appropriately suppress warpage.

### BRIEF DESCRIPTION OF THE DRAWINGS

FIG. 1 is a plan view illustrating a configuration of a package including a ceramic substrate according to a first embodiment.

FIG. 2 is a cross-sectional view taken along the line II-II′ in FIG. 1.

FIG. 3 is an explanatory diagram for describing a method for manufacturing a ceramic substrate.

FIG. 4 is a plan view illustrating a mother multilayer body.

FIG. 5 is a cross-sectional view schematically illustrating the mother multilayer body after firing.

FIG. 6 is an explanatory diagram for describing a method for manufacturing a ceramic substrate according to a modified example.

FIG. 7 is an explanatory diagram for describing a method for manufacturing a ceramic substrate according to a second embodiment.

FIG. 8 is an explanatory diagram for describing a method for manufacturing a ceramic substrate according to a third embodiment.

FIG. 9 is an enlarged plan view of a mother multilayer body according to the third embodiment.

FIG. 10 is an explanatory diagram for describing a method for manufacturing a ceramic substrate according to a fourth embodiment.

FIG. 11 is a cross-sectional view schematically illustrating a configuration of a shrinkage suppressing green sheet.

### DETAILED DESCRIPTION OF THE PREFERRED EMBODIMENTS

Hereinafter, embodiments of a method for manufacturing a ceramic substrate and a ceramic substrate according to the present invention will be described in detail with reference to the accompanying drawings. It should be noted that the present invention is not limited to the embodiments. It will be apparent that the embodiments are illustrative only, and that partial substitutions or combinations of the configurations described in different embodiments may be possible. In the second embodiment and the subsequent embodiments, description of matters common to the first embodiment will be omitted, and only different points will be described. In particular, similar actions and effects according to a similar configuration will not be sequentially described for each embodiment.

### First Embodiment

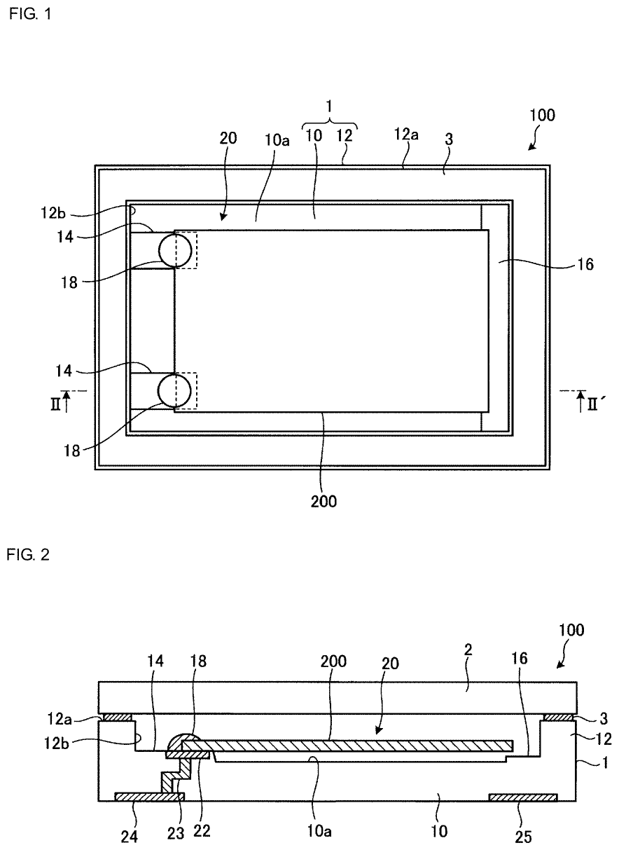

FIG. 1 is a plan view illustrating a configuration of a package including a ceramic substrate according to a first embodiment. FIG. 2 is a cross-sectional view taken along the line II-II′ in FIG. 1. Note that FIG. 1 is a plan view of a ceramic substrate 1 with a lid 2 of a package 100 removed.

As illustrated in FIG. 1, the package 100 includes the ceramic substrate 1. The ceramic substrate 1 has a substrate bottom portion 10 and a wall portion 12. The wall portion 12 surrounds a mounting surface 10a of the substrate bottom portion 10 and is provided in a frame shape. In other words, the ceramic substrate 1 has a recessed portion 20 provided on an upper surface thereof. The ceramic substrate 1 has a rectangular shape in a plan view. Note that in the following description, a plan view indicates an arrangement relationship viewed from a direction perpendicular to the mounting surface 10a.

An electronic component 200 is housed in the recessed portion 20 of the ceramic substrate 1. Specifically, the electronic component 200 is a crystal unit. Pedestals 14 for mounting the electronic component 200 are provided on the mounting surface 10a of the substrate bottom portion 10. The pedestals 14 are provided near corner portions of the mounting surface 10a, and are connected to an inner wall surface 12b of the wall portion 12. Further, a supporting portion 16 is provided on the mounting surface 10a of the substrate bottom portion 10. The supporting portion 16 is disposed on a side opposite to the pedestals 14. One end side of the electronic component 200 is joined on the pedestals 14 by using joining members 18. The other end side of the electronic component 200 is positioned on an upper side of the supporting portion 16. The electronic component 200 is separately disposed from the mounting surface 10a, the supporting portion 16, and the inner wall surface 12b of the wall portion 12.

As illustrated in FIG. 2, a connection electrode 22 electrically connected to the electronic component 200 is provided on an upper surface of the pedestal 14. Further, bottom electrodes 24 and 25 are provided on a lower surface of the ceramic substrate 1. The connection electrode 22 and the bottom electrode 24 are electrically connected to each other with a via 23 being interposed therebetween and being provided in the substrate bottom portion 10.

A metallized layer 3 is provided on an upper surface 12a of the wall portion 12. The lid 2 is joined to the ceramic substrate 1 with the metallized layer 3 interposed therebetween. Thereby, a space surrounded by the substrate bottom portion 10, the wall portion 12, and the lid 2 is hermetically sealed.

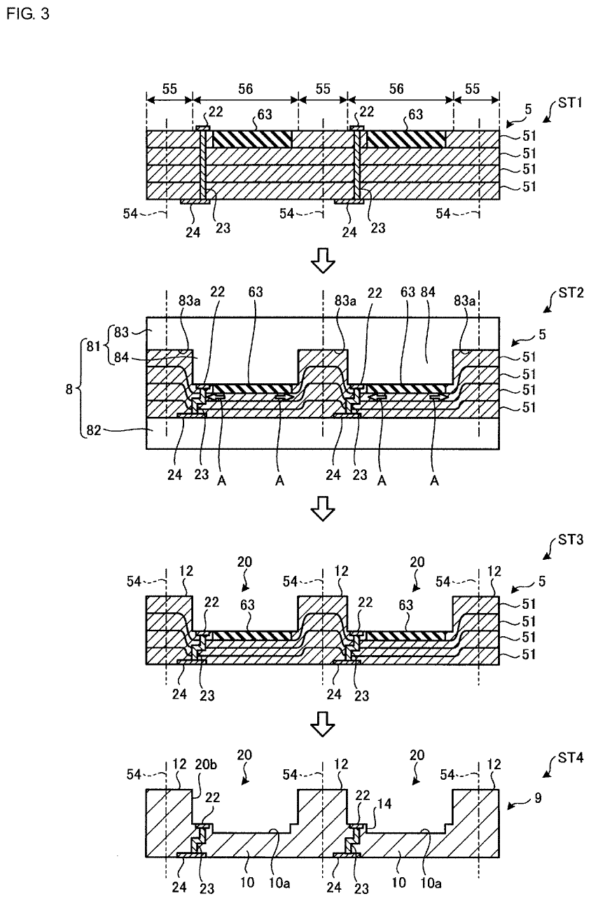

Next, a method for manufacturing the ceramic substrate 1 will be described. FIG. 3 is an explanatory diagram for describing a method for manufacturing a ceramic substrate. As illustrated in FIG. 3, the method for manufacturing the ceramic substrate 1 includes preparing a plurality of ceramic green sheets 51, providing a disappearance material 63 in a recessed portion formation planned region 56 of at least one ceramic green sheet 51 of the plurality of ceramic green sheets 51, and forming a mother multilayer body 5 by laminating the plurality of ceramic green sheets 51 (step ST1).

The ceramic green sheet 51 contains ceramic powder containing aluminum oxide (Al₂O₃) as a main component, and a resin material such as an organic binder and thermoplastic resin. The ceramic green sheet 51 is coated and formed by using, for example, a doctor blade, a lip coater, or the like.

The disappearance material 63 is a material that disappears after firing. As the disappearance material 63, for example, resin paste containing crosslinked acrylic resin beads is used. By printing with the resin paste on a cavity provided in the ceramic green sheet 51, the disappearance material 63 can be formed on the ceramic green sheet 51. Alternatively, the disappearance material 63 may be carbon or wax. The plurality of ceramic green sheets 51 is laminated such that the ceramic green sheet 51 provided with the disappearance material 63 is positioned on the uppermost layer.

Further, the mother multilayer body 5 has a wall portion formation planned region 55 and the recessed portion formation planned regions 56. The wall portion formation planned region 55 is a region where the wall portion 12 of the ceramic substrate 1 is to be formed after firing and division of the mother multilayer body 5. The recessed portion formation planned region 56 is a region in which the recessed portion 20 of the ceramic substrate 1 is to be formed after the firing and division of the mother multilayer body 5. In the present embodiment, the disappearance material 63 is provided in a partial region of the recessed portion formation planned region 56, that is, in a region that does not overlap with the connection electrode 22 and the via 23.

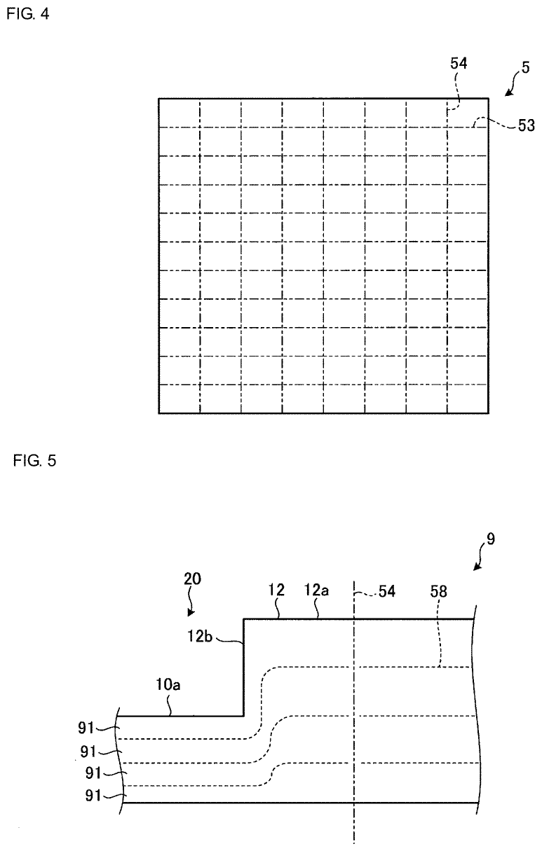

FIG. 4 is a plan view illustrating the mother multilayer body. As illustrated in FIG. 4, in the mother multilayer body 5, division planned lines 53 and 54 are provided in a matrix shape. The mother multilayer body 5 is divided into individual ceramic substrates 1 along the division planed lines 53 and 54 after firing. That is, a region surrounded by the division planned lines 53 and 54 corresponds to one ceramic substrate 1. In the mother multilayer body 5, grooves for division may be formed at positions overlapping with the division planned lines 53 and 54. For example, a roller breaker may be used as equipment for division into individual ceramic substrates 1, and a dicer may be used as the equipment.

Next, as illustrated in FIG. 3, a pressing jig 8 forms the recessed portions 20 in the mother multilayer body 5 by pressing the recessed portion formation planned regions 56 of the mother multilayer body 5 (step ST2). The pressing jig 8 has an upper mold 81 and a lower mold 82. The mother multilayer body 5 is disposed between the lower mold 82 and the upper mold 81. The upper mold 81 has a base 83 and protruding portions 84.

The upper mold 81 presses the mother multilayer body 5 from an upper surface side of the mother multilayer body 5. As a result, first, the recessed portion formation planned regions 56 of the mother multilayer body 5 are pressed by the protruding portions 84. A lower surface of the protruding portion 84 contacts the disappearance material 63 and the ceramic green sheet 51 around the disappearance material 63. The plurality of ceramic green sheets 51 and the disappearance material 63 deform along shapes of the protruding portions 84 due to the pressure applied from the protruding portions 84. That is, the plurality of ceramic green sheets 51 and the disappearance material 63 in the recessed portion formation planned region 56 are thinned, and the plurality of ceramic green sheets 51 is pushed out in the directions indicated by the arrows A, and flows to a wall portion formation planned region 55 side. A thickness of the wall portion formation planned region 55 is larger than that of the recessed portion formation planned region 56.

Further, when the upper mold 81 performs pressing, the mother multilayer body 5 deforms so as to cover lower surfaces and side surfaces of the protruding portions 84, and the wall portion formation planned region 55 is in contact with a lower surface 83a of the base 83. The plurality of ceramic green sheets 51 is curved along the lower surfaces and the side surfaces of the protruding portions 84, and the lower surface 83a of the base 83. The disappearance material 63 is formed to be flat along the lower surface of the protruding portion 84. As a result, the shapes of the protruding portions 84 are transferred to the mother multilayer body 5.

Pressure larger than that to the wall portion formation planned region 55 is applied to the recessed portion formation planned region 56. Accordingly, density distribution of the plurality of ceramic green sheets 51 occurs in the recessed portion formation planned region 56 and the wall portion formation planned region 55.

Next, by removing the pressing jig 8, the mother multilayer body 5 having the recessed portions 20 can be obtained (step ST3). The recessed portion formation planned region 56 of the mother multilayer body 5 includes the plurality of ceramic green sheets 51 and the disappearance material 63. The wall portion formation planned region 55 includes the laminated plurality of ceramic green sheets 51.

Next, the mother multilayer body 5 is fired at a predetermined temperature (step ST4). As a result, the disappearance materials 63 disappear, and the plurality of ceramic green sheets 51 are sintered together, thereby obtaining a fired mother multilayer body 9. The fired mother multilayer body 9 is formed with a plurality of recessed portions 20 on an upper surface thereof. In other words, the fired mother multilayer body 9 is arrayed with a plurality of substrate bottom portions 10 and a plurality of wall portions 12 that become the individual ceramic substrates 1 after the division. In each of the plurality of recessed portions 20, a step is formed due to the disappearance of the disappearance material 63. The mounting surface 10a is formed in a region in which the disappearance material 63 has been provided in the recessed portion formation planned region 56. The pedestal 14 is formed in a region in which the disappearance material 63 is not provided in the recessed portion formation planned region 56.

According to the method for manufacturing the ceramic substrate 1 of the present embodiment, in the mother multilayer body 5, the disappearance material 63 is provided in the recessed portion formation planned region 56. For this reason, the recessed portion 20 after the firing can be formed deep at the same pressure, compared to a case where the disappearance material 63 is not provided. In other words, the recessed portion 20 having the same depth as that of the recessed portion 20 in the case where the disappearance material 63 is not provided can be formed at a low pressure.

Accordingly, in the present embodiment, occurrence of warpage of the fired mother multilayer body 9 can be suppressed even when density distribution occurs in the recessed portion formation planned region 56 and the wall portion formation planned region 55 in the mother multilayer body 5 before the firing. As a result, it is possible to suppress the warpage of the ceramic substrate 1 formed by dividing the fired mother multilayer body 9.

FIG. 5 is a cross-sectional view schematically illustrating the fired mother multilayer body. As illustrated in FIG. 5, the fired mother multilayer body 9 has a plurality of ceramic layers 91. The ceramic layers 91 are layers formed by sintering the ceramic green sheets 51. Orientations of grain boundaries 58 indicating interlayers of the plurality of ceramic layers 91 are curved along the mounting surface 10a, and the inner wall surface 12b and the upper surface 12a of the wall portion 12 due to the flow of the plurality of ceramic green sheets 51 in the press process.

It should be noted that the configuration of the first embodiment described above is merely an example, and may be modified as appropriate. For example, the disappearance material 63 is provided on one layer of the ceramic green sheet 51 positioned on the uppermost layer, but may be provided in or on two or more layers of the ceramic green sheets 51. The number of the plurality of ceramic green sheets 51 configuring the mother multilayer body 5 is not limited to four, and may be equal to or larger than five, and may be equal to or smaller than three.

Further, a cross-sectional shape of the recessed portion 20 has a partial shape of a rectangular shape having corner portions, but is not limited thereto. A connection portion between the inner wall surface 12b of the recessed portion 20 and the mounting surface 10a may be formed to have a curved surface that is curved. Alternatively, the mounting surface 10a of the recessed portion 20 may be formed to have a curved surface.

Further, the electronic component 200 illustrated in FIG. 1 and FIG. 2 is not limited to a crystal unit, and may be another electronic component.

### Modified Example

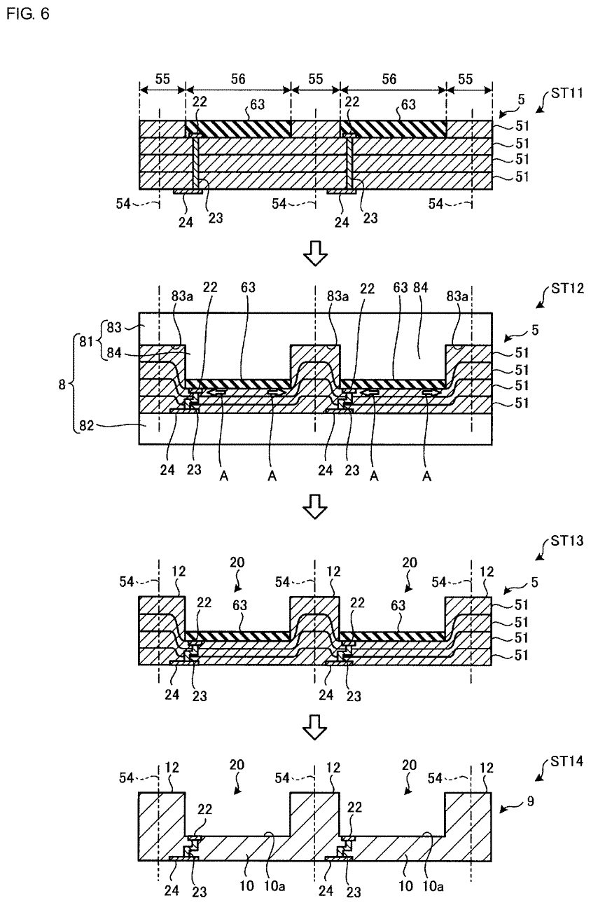

FIG. 6 is an explanatory diagram for describing a method for manufacturing a ceramic substrate according to a modified example. Note that, in the following description, the same constituent elements as those in the above-described embodiment are denoted by the same reference numerals, and the description thereof will be omitted. In the modified example, a configuration in which the disappearance material 63 is provided in an entire region of the recessed portion formation planned region 56, unlike the above-described first embodiment, will be described.

Specifically, as illustrated in FIG. 6, a plurality of ceramic green sheets 51 is laminated to form the mother multilayer body 5, and the disappearance material 63 is provided in a region overlapping with the connection electrode 22 and the via 23 (step ST11).

The pressing jig 8 abuts against the disappearance material 63 on the entire lower surface of the protruding portion 84, and the recessed portion formation planned region 56 of the mother multilayer body 5 is pressed (step ST12). As a result, the recessed portion 20 is formed in the mother multilayer body 5. The connection electrode 22 and the via 23 are pushed into the ceramic green sheets 51 such that an upper surface of the connection electrode 22 and an upper surface of the ceramic green sheet 51 form the same surface.

Next, by removing the pressing jig 8, the mother multilayer body 5 having the recessed portions 20 each of which has the disappearance material 63 as a bottom surface can be obtained (step ST13).

Next, the mother multilayer body 5 is fired at a predetermined temperature (step ST14). Thereby, the disappearance material 63 disappears, and the bottom surface of the recessed portion 20 is formed on the flat mounting surface 10a having no step.

As described above, a shape and a size of the disappearance material 63 to be provided on the ceramic green sheet 51 can be made different depending on the shape of the recessed portion 20 of the ceramic substrate 1 after firing.

### Second Embodiment

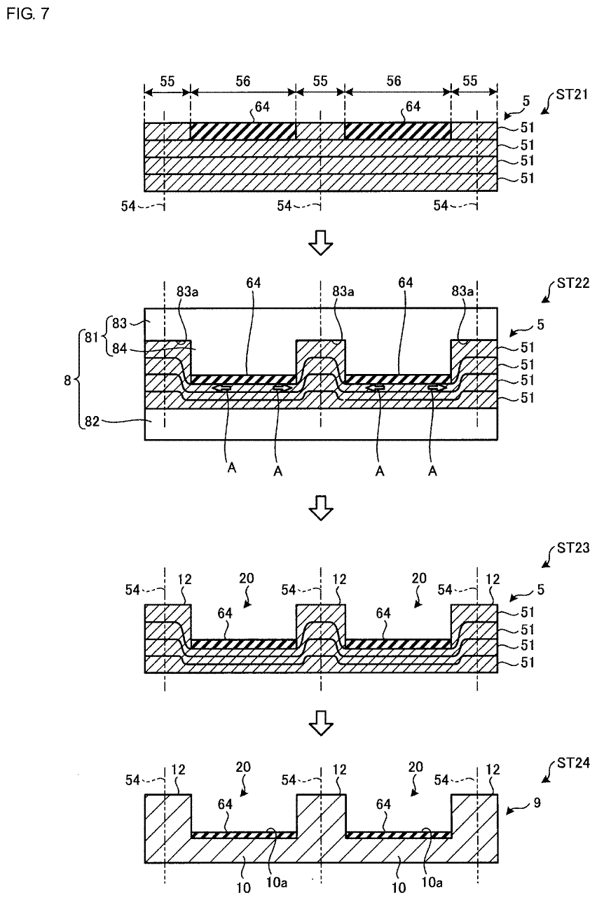

FIG. 7 is an explanatory diagram for describing a method for manufacturing a ceramic substrate according to a second embodiment. In the second embodiment, unlike the first embodiment and the modified example described above, description will be given of a configuration in which a high shrinkage rate material 64, instead of the disappearance material 63, is provided in the recessed portion formation planned region 56.

As illustrated in FIG. 7, the method for manufacturing the ceramic substrate 1 includes preparing a plurality of ceramic green sheets 51, providing the high shrinkage rate material 64 in the recessed portion formation planned region 56 of at least one ceramic green sheet 51 of the plurality of ceramic green sheets 51, and forming the mother multilayer body 5 by laminating the plurality of ceramic green sheets 51 (step ST21).

The high shrinkage rate material 64 is a material having a higher shrinkage rate in firing than that of the ceramic green sheet 51. The high shrinkage rate material 64 is, for example, a material that does not disappear during firing, such as carbon or wax. The plurality of ceramic green sheets 51 is laminated such that the ceramic green sheet 51 provided with the high shrinkage rate material 64 is positioned on the uppermost layer.

Next, the pressing jig 8 forms the recessed portions 20 in the mother multilayer body 5 by pressing the recessed portion formation planned regions 56 of the mother multilayer body 5 (step ST22). Next, by removing the pressing jig 8, the mother multilayer body 5 having the recessed portions 20 can be obtained (step ST23). The recessed portion formation planned region 56 of the mother multilayer body 5 is formed by laminating the plurality of ceramic green sheets 51 and the high shrinkage rate material 64. The wall portion formation planned region 55 is formed by laminating the plurality of ceramic green sheets 51.

Next, the mother multilayer body 5 is fired at a predetermined temperature (step ST24). As a result, a part of the high shrinkage rate material 64 remains on the bottom surface of the recessed portion 20, and the plurality of ceramic green sheets 51 are sintered together to obtain the fired mother multilayer body 9. The mounting surface 10a is formed by laminating the high shrinkage rate material 64 on the ceramic layers 91 in which the ceramic green sheets 51 are sintered.

Also in the second embodiment, similarly to the first embodiment, the recessed portion 20 after the firing can be formed deep at the same pressure, compared with a case where the high shrinkage rate material 64 is not provided. In other words, the recessed portion 20 having the same depth as that of the recessed portion 20 in the case where the high shrinkage rate material 64 is not provided can be formed at a small pressure.

In the second embodiment, the high shrinkage rate material 64 is provided on one layer of the ceramic green sheet 51 positioned on the uppermost layer, but may be provided in or on two or more layers of the ceramic green sheets 51.

### Third Embodiment

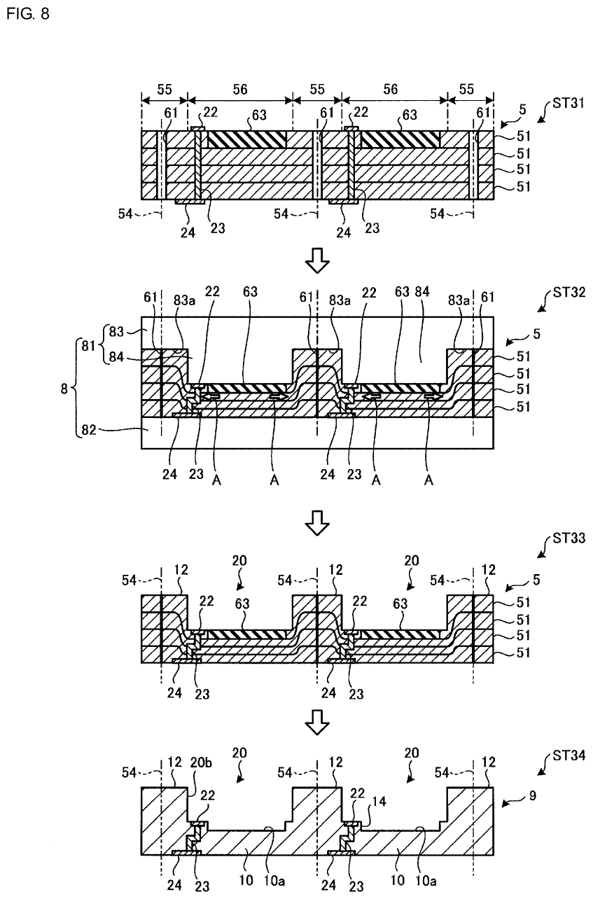

FIG. 8 is an explanatory diagram for describing a method for manufacturing a ceramic substrate according to a third embodiment. In the third embodiment, a configuration in which hole portions 61 are provided in the mother multilayer body 5 will be described, unlike the embodiments and the modified example described above.

More specifically, as illustrated in FIG. 8, the method for manufacturing the ceramic substrate 1 includes forming the hole portions 61 in a plurality of ceramic green sheets 51, and forming the mother multilayer body 5 by laminating the plurality of ceramic green sheets 51 (step ST31).

The hole portion 61 is formed at a position that does not overlap with the recessed portion formation planned region 56 of the plurality of ceramic green sheets 51, and that overlaps with the division planned line 54. That is, the plurality of hole portions 61 is provided in the wall portion formation planned regions 55 of the mother multilayer body 5. The plurality of hole portions 61 are provided so as to penetrate from an upper surface to a lower surface of the mother multilayer body 5.

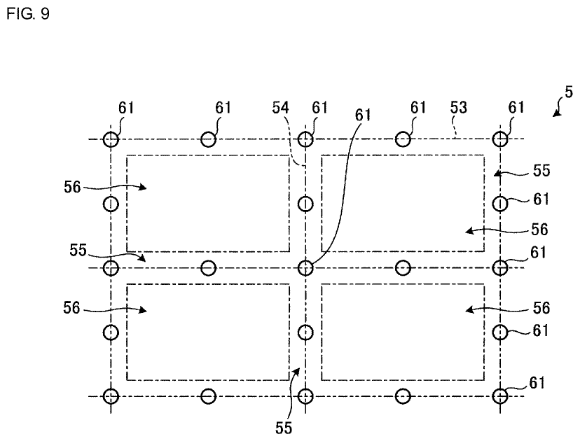

FIG. 9 is an enlarged plan view of the mother multilayer body. Note that, in FIG. 9, the mother multilayer body 5 before pressing is illustrated after the plurality of ceramic green sheets 51 is laminated. As illustrated in FIG. 9, each of the plurality of hole portions 61 has a circular shape in a plan view, and the plurality of hole portions 61 is arrayed along the division planned lines 53 and 54. More specifically, the plurality of hole portions 61 is provided at positions overlapping with intersections of the division planned lines 53 and the division planned lines 54. The plurality of hole portions 61 is also provided at positions overlapping with the division planned line 53 or 54 between the intersections.

Next, as illustrated in FIG. 8, the pressing jig 8 forms the recessed portions 20 in the mother multilayer body 5 by pressing the recessed portion formation planned regions 56 of the mother multilayer body 5 (step ST32). The plurality of ceramic green sheets 51 and the disappearance material 63 deform along the shapes of the protruding portions 84 due to the pressure applied from the protruding portions 84. That is, the ceramic green sheets 51 and the disappearance material 63 in the recessed portion formation planned region 56 are thinned, and the ceramic green sheets 51 are pushed out in the directions indicated by the arrows A, and flow to the wall portion formation planned region 55 side. A thickness of the wall portion formation planned region 55 is larger than that of the recessed portion formation planned region 56, and a width of the hole portion 61 becomes small due to the flow of the ceramic green sheets 51.

Further, when the upper mold 81 performs pressing, the mother multilayer body 5 deforms so as to cover lower surfaces and side surfaces of the protruding portions 84, and the wall portion formation planned region 55 is in contact with the lower surface 83a of the base 83. As a result, the shapes of the protruding portions 84 are transferred to the mother multilayer body 5. Further, an inner wall of the hole portion 61 is brought into close contact due to the flow of the plurality of ceramic green sheets 51 in the recessed portion formation planned region 56, and the mother multilayer body 5 is integrally formed on the division planned line 54.

Then, the mother multilayer body 5 having the recessed portions 20 can be obtained by removing the pressing jig 8 (step ST33).

Next, the mother multilayer body 5 is fired at a predetermined temperature (step ST34). Accordingly, the disappearance materials 63 disappear, and the plurality of ceramic green sheets 51 are sintered together to obtain the fired mother multilayer body 9.

According to the method for manufacturing the ceramic substrate 1 of the third embodiment, since the hole portions 61 are provided in the mother multilayer body 5, the fluidity of the plurality of ceramic green sheets 51 in the press process can be improved. That is, when pressure is applied to the plurality of ceramic green sheets 51 by the pressing jig 8, the plurality of ceramic green sheets 51 in the recessed portion formation planned region 56 easily flows to the wall portion formation planned region 55 side by the hole portions 61.

As a result, in the third embodiment, compared with the first embodiment and the second embodiment, the distribution of the pressure to the plurality of ceramic green sheets 51 in the press process is relaxed, and the recessed portion 20 can be formed by deforming the recessed portion formation planned region 56 and the wall portion formation planned region 55 at a low pressure. Alternatively, it is possible to form a deep recessed portion 20 at the same pressure, compared to a case where the hole portions 61 are not formed.

Thus, in the mother multilayer body 5 after the press process, it is possible to suppress a difference in density of the plurality of ceramic green sheets 51 between the recessed portion formation planned region 56 and the wall portion formation planned region 55. As a result, it is possible to suppress the warpage of the ceramic substrate 1 formed after the firing and division of the mother multilayer body 5.

In addition, as illustrated in FIG. 9, the plurality of hole portions 61 are provided so as to surround the periphery of the recessed portion formation planned region 56. More preferably, the plurality of hole portions 61 are provided at positions symmetrical to each other with each recessed portion formation planned region 56 sandwiched therebetween. This makes it easier for the plurality of ceramic green sheets 51 in the recessed portion formation planned region 56 to flow uniformly to the surrounding wall portion formation planned region 55 side when pressing is performed by the pressing jig 8.

Note that, in the third embodiment, the number, arrangement, and shape in a plan view of the hole portions 61 can be changed as appropriate. For example, in FIG. 9, two or more hole portions 61 may be arrayed between the adjacent intersections. Alternatively, the hole portions 61 may be provided only at positions overlapping with the intersections, and the hole portions 61 may not necessarily be arrayed between the adjacent intersections. The shape of the hole portion 61 in a plan view is not limited to a circular shape, and may be other shapes, such as a rectangular shape, a rhombic shape, a cross shape, or a polygonal shape. Further, the plurality of hole portions 61 is not limited to being provided so as to penetrate from the upper surface to the lower surface of the mother multilayer body 5, and may be provided from the upper surface of the mother multilayer body 5 to the ceramic green sheet 51 of an intermediate layer.

### Fourth Embodiment

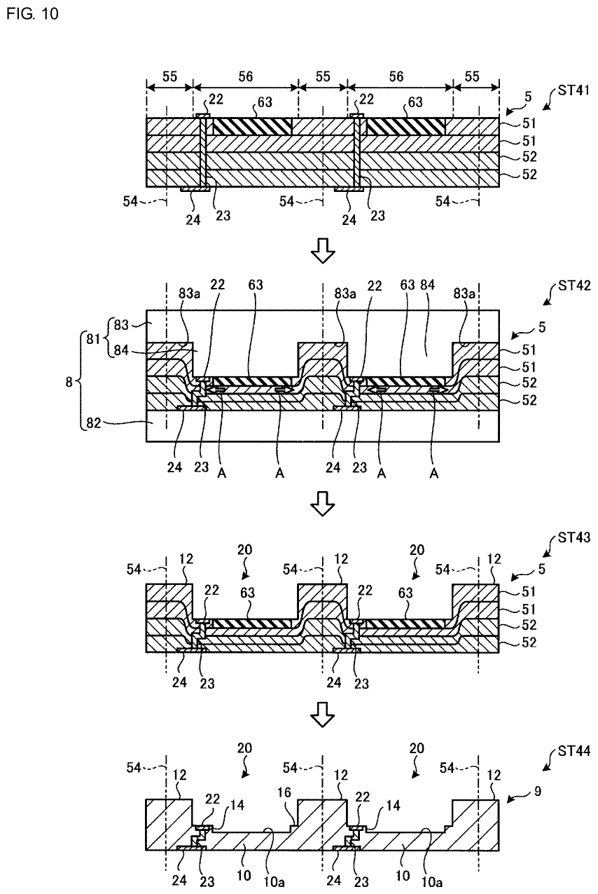

FIG. 10 is an explanatory diagram for describing a method for manufacturing a ceramic substrate according to a fourth embodiment. In the fourth embodiment, a configuration in which the mother multilayer body 5 includes shrinkage suppressing green sheets 52 will be described, unlike the above-described embodiments and modified example.

More specifically, as illustrated in FIG. 10, the method for manufacturing the ceramic substrate 1 includes preparing a plurality of ceramic green sheets 51 and a plurality of shrinkage suppressing green sheets 52, and forming the mother multilayer body 5 by laminating the plurality of ceramic green sheets 51 on the plurality of shrinkage suppressing green sheets 52 (step ST41).

Among the plurality of ceramic green sheets 51, at least the ceramic green sheet 51 on the uppermost layer is provided with the disappearance material 63. Further, the plurality of ceramic green sheets 51 and the plurality of shrinkage suppressing green sheets 52 are continuously provided across the wall portion formation planned region 55 and the recessed portion formation planned region 56.

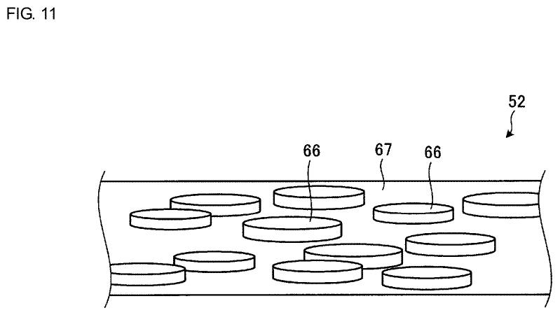

The shrinkage suppressing green sheet 52 has characteristics that its own planar shrinkage rate is smaller than 1% during firing. The shrinkage suppressing green sheet 52 has a smaller planar shrinkage rate than that of the ceramic green sheet 51. FIG. 11 is a cross-sectional view schematically illustrating a configuration of a shrinkage suppressing green sheet. As illustrated in FIG. 11, the shrinkage suppressing green sheet 52 includes plate-shaped ceramic fillers 66, and a resin material 67 such as an organic binder and thermoplastic resin. The plate-shaped ceramic filler 66 is, for example, plate-shaped alumina.

The shrinkage suppressing green sheet 52 is coated and formed by using, for example, a doctor blade, a lip coater, or the like. Accordingly, orientations of the plurality of plate-shaped ceramic fillers 66 are aligned with an in-plane direction of the shrinkage suppressing green sheet 52. As a result, the shrinkage suppressing green sheet 52 can have a smaller planar shrinkage rate than that of the ceramic green sheet 51. Note that the shrinkage suppressing green sheet 52 may have spherical alumina. The plurality of ceramic green sheets 51 and the plurality of shrinkage suppressing green sheets 52 may have different blending ratios of the plate-shaped ceramic filler 66 and the spherical alumina for each layer.

Next, as illustrated in FIG. 10, the pressing jig 8 forms the recessed portions 20 in the mother multilayer body 5 by pressing the recessed portion formation planned regions 56 of the mother multilayer body 5 (step ST42).

The upper mold 81 presses the mother multilayer body 5 from the upper surface side of the mother multilayer body 5. As a result, first, the recessed portion formation planned regions 56 of the mother multilayer body 5 are pressed by the protruding portions 84. The plurality of ceramic green sheets 51 and the plurality of shrinkage suppressing green sheets 52 deform along the shapes of the protruding portions 84 due to the pressure applied from the protruding portions 84. That is, the plurality of ceramic green sheets 51, the disappearance material 63, and the plurality of shrinkage suppressing green sheets 52 in the recessed portion formation planned region 56 are thinned, and the plurality of ceramic green sheets 51 and the plurality of shrinkage suppressing green sheets 52 are pushed out in the directions indicated by the arrows A, and flow to the wall portion formation planned region 55 side. A thickness of the wall portion formation planned region 55 is larger than that of the recessed portion formation planned region 56.

Further, when the upper mold 81 performs pressing, the mother multilayer body 5 deforms so as to cover lower surfaces and side surfaces of the protruding portions 84, and the wall portion formation planned region 55 is in contact with the lower surface 83a of the base 83. The plurality of ceramic green sheets 51 and the plurality of shrinkage suppressing green sheets 52 are curved along the lower surfaces, and the side surfaces of the protruding portions 84, and the lower surface 83a of the base 83. As a result, the shapes of the protruding portions 84 are transferred to the mother multilayer body 5.

Pressure larger than that to the wall portion formation planned region 55 is applied to the recessed portion formation planned region 56. Accordingly, density distribution of the plurality of ceramic green sheets 51 and the plurality of shrinkage suppressing green sheets 52 occurs in the recessed portion formation planned region 56 and the wall portion formation planned region 55.

Next, by removing the pressing jig 8, the mother multilayer body 5 having the recessed portions 20 can be obtained (step ST43). The recessed portion formation planned region 56 of the mother multilayer body 5 is formed by laminating the plurality of ceramic green sheets 51, the disappearance material 63, and the plurality of shrinkage suppressing green sheets 52. The wall portion formation planned region 55 of the mother multilayer body 5 is formed by laminating the plurality of ceramic green sheets 51 and the plurality of shrinkage suppressing green sheets 52.

Next, the mother multilayer body 5 is fired at a predetermined temperature (step ST44). Accordingly, the disappearance materials 63 disappear, and the plurality of ceramic green sheets 51 and the plurality of shrinkage suppressing green sheets 52 are sintered together to obtain the fired mother multilayer body 9. The fired mother multilayer body 9 is formed with a plurality of recessed portions 20 on an upper surface thereof. Each of the plurality of recessed portions 20 has the mounting surface 10a formed due to disappearance of the disappearance material 63.

According to the method for manufacturing the ceramic substrate 1 of the present embodiment, in the mother multilayer body 5, the plurality of ceramic green sheets 51 are laminated on the plurality of shrinkage suppressing green sheets 52. For this reason, shrinkage of the plurality of ceramic green sheets 51 in a planar direction during firing is suppressed by the plurality of shrinkage suppressing green sheets 52. As a result, in the mother multilayer body 5, the shrinkage in a thickness direction becomes dominant during the firing.

Accordingly, in the fourth embodiment, occurrence of warpage of the fired mother multilayer body 9 can be suppressed even when density distribution occurs in the recessed portion formation planned region 56 and the wall portion formation planned region 55 in the mother multilayer body 5 before the firing. As a result, it is possible to suppress the warpage of the ceramic substrate 1 formed by dividing the fired mother multilayer body 9.

Note that the configuration of the fourth embodiment may be combined with one of the second embodiment, the third embodiment, and the modified example.

In the fourth embodiment, the plurality of ceramic green sheets 51 and the plurality of shrinkage suppressing green sheets 52 are laminated two by two, but the present invention is not limited thereto. The mother multilayer body 5 only needs to include at least one shrinkage suppressing green sheet 52. In addition, the number of the shrinkage suppressing green sheets 52 may be equal to or larger than three. Further, the number of ceramic green sheets 51 may be one or be equal to or larger than three.

Note that the above-described embodiments are intended to facilitate understanding of the present invention, and are not intended to limit the present invention. The present invention can be modified/improved without departing from the gist thereof, and the present invention also includes equivalents thereof.

### REFERENCE SIGNS LIST

1 CERAMIC SUBSTRATE
2 LID
3 METALLIZED LAYER
5 MOTHER MULTILAYER BODY
8 PRESSING JIG
9 MOTHER MULTILAYER BODY AFTER FIRING
10 SUBSTRATE BOTTOM PORTION
10a MOUNTING SURFACE
12 WALL PORTION
12a UPPER SURFACE
12b INNER WALL SURFACE
14 PEDESTAL
16 SUPPORTING PORTION
18 JOINING MEMBER
20 RECESSED PORTION
22 CONNECTION ELECTRODE
23 VIA
24, 25 BOTTOM ELECTRODE
51 CERAMIC GREEN SHEET
52 SHRINKAGE SUPPRESSING GREEN SHEET
53, 54 DIVISION PLANNED LINE
55 WALL PORTION FORMATION PLANNED REGION
56 RECESSED PORTION FORMATION PLANNED REGION
58 GRAIN BOUNDARY
61 HOLE PORTION
63 DISAPPEARANCE MATERIAL
64 HIGH SHRINKAGE RATE MATERIAL
66 PLATE-SHAPED CERAMIC FILLER
67 RESIN MATERIAL
81 UPPER MOLD
82 LOWER MOLD
83 BASE
84 PROTRUDING PORTION
91 CERAMIC LAYER
100 PACKAGE
200 ELECTRONIC COMPONENT
A ARROW

1. A method for manufacturing a ceramic substrate, the method comprising:
preparing a plurality of ceramic green sheets, at least one of the plurality of ceramic green sheets having a disappearance material that disappears by firing in a recessed portion formation planned region of the at least one of the plurality of ceramic green sheets;
forming a mother multilayer body by laminating the plurality of ceramic green sheets such that the at least the one ceramic green sheet having the disappearance material is positioned on an uppermost layer of the mother multilayer body; and
forming a recessed portion in the mother multilayer body before firing by pressing the recessed portion formation planned region of the mother multilayer body.

2. The method for manufacturing the ceramic substrate according to claim 1, wherein the disappearance material is located in a partial region of the recessed portion formation planned region.

3. The method for manufacturing the ceramic substrate according to claim 1, wherein the disappearance material is provided in an entire region of the recessed portion formation planned region.

4. The method for manufacturing the ceramic substrate according to claim 1, the method further comprising:
forming a hole portion in at least one or more of the plurality of ceramic green sheets of the mother multilayer body at a position that does not overlap with the recessed portion formation planned region and that overlaps with a division planned line where the mother multilayer body is to be divided into individual ceramic substrates after firing.

5. The method for manufacturing the ceramic substrate according to claim 4, wherein, during the forming of the recessed portion, the mother multilayer body is integrally formed on the division planned line by bringing an inner wall of the hole portion into close contact due to a flow of the plurality of ceramic green sheets during the pressing of the recessed portion formation planned region of the mother multilayer body.

6. The method for manufacturing the ceramic substrate according to claim 1, the method further comprising:
laminating the plurality of ceramic green sheets on at least one shrinkage suppressing green sheet during the forming of the mother multilayer body, the at least one shrinkage suppressing green sheet having a planar shrinkage rate in firing smaller than a planar shrinkage rate in firing of the plurality of ceramic green sheets.

7. The method for manufacturing the ceramic substrate according to claim 6, wherein the at least one shrinkage suppressing green sheet includes a plate-shaped ceramic filler.

8. The method for manufacturing the ceramic substrate according to claim 7, wherein the plate-shaped ceramic filler is alumina.

9. The method for manufacturing the ceramic substrate according to claim 1, the method further comprising firing the mother multilayer body.

10. A method for manufacturing a ceramic substrate, the method comprising:
preparing a plurality of ceramic green sheets, at least one of the plurality of ceramic green sheets having a high shrinkage rate material having a higher shrinkage rate in firing than a shrinkage rate in firing of the plurality of ceramic green sheets in a recessed portion formation planned region of the at least one of the plurality of ceramic green sheets;
forming a mother multilayer body by laminating the plurality of the ceramic green sheets such that the at least the one ceramic green sheet having the high shrinkage rate material is positioned on an uppermost layer of the mother multilayer body; and
forming a recessed portion in the mother multilayer body before firing by pressing the recessed portion formation planned region of the mother multilayer body.

11. The method for manufacturing the ceramic substrate according to claim 10, the method further comprising:
forming a hole portion in at least one or more of the plurality of ceramic green sheets of the mother multilayer body at a position that does not overlap with the recessed portion formation planned region and that overlaps with a division planned line where the mother multilayer body is to be divided into individual ceramic substrates after firing.

12. The method for manufacturing the ceramic substrate according to claim 11, wherein, during the forming of the recessed portion, the mother multilayer body is integrally formed on the division planned line by bringing an inner wall of the hole portion into close contact due to a flow of the plurality of ceramic green sheets during the pressing of the recessed portion formation planned region of the mother multilayer body.

13. The method for manufacturing the ceramic substrate according to claim 10, the method further comprising:
laminating the plurality of ceramic green sheets on at least one shrinkage suppressing green sheet during the forming of the mother multilayer body, the at least one shrinkage suppressing green sheet having a planar shrinkage rate in firing smaller than a planar shrinkage rate in firing of the plurality of ceramic green sheets.

14. The method for manufacturing the ceramic substrate according to claim 13, wherein the shrinkage suppressing green sheet includes a plate-shaped ceramic filler.

15. The method for manufacturing the ceramic substrate according to claim 14, wherein the plate-shaped ceramic filler is alumina.

16. The method for manufacturing the ceramic substrate according to claim 10, the method further comprising firing the mother multilayer body.

17. A ceramic substrate comprising:
a substrate comprising a plurality of laminated ceramic layers, the substrate having a bottom portion with a mounting surface;
a wall portion on the bottom portion of the substrate and surrounding the mounting surface; and
a high shrinkage rate material having a higher shrinkage rate in firing than a shrinkage rate in firing of the plurality of ceramic layers laminated on the plurality of the ceramic layers in a region overlapping with the mounting surface, wherein
an orientation of a grain boundary indicating an interlayer between the plurality of laminated ceramic layers is curved along the mounting surface and an inner wall of the wall portion.

18. The ceramic substrate according to claim 17, wherein the substrate further comprises at least one shrinkage suppressing green sheet laminated with the plurality of ceramic green sheets, the at least one shrinkage suppressing green sheet having a planar shrinkage rate in firing smaller than a planar shrinkage rate in firing of the plurality of ceramic green sheets.

19. The ceramic substrate according to claim 18, wherein the at least one shrinkage suppressing green sheet includes a plate-shaped ceramic filler.

20. The ceramic substrate according to claim 19, wherein the plate-shaped ceramic filler is alumina.
